(19) United States
(12) Patent Application Publication
(10) Pub. No.: US 2007/0092844 A1
(43) Pub. Date: Apr. 26, 2007

(54) Method to form photo patterns

(75) Inventor: Chin Cheng Yang, Hsinchu (TW)

Correspondence Address: MARTINE PENILLA & GENCARELLA, LLP, 710 LAKEWAY DRIVE, SUITE 200, SUNNYVALE, CA, 94085, US

(73) Assignee: Macronix International Co., Ltd.

(21) Appl. No.: 11/255,791

(22) Filed: Oct. 21, 2005

(51) Int. Cl. G03F 7/20

(52) U.S. Cl. 430/322; 430/394

(57) ABSTRACT

A method for forming photo patterns on a photoresist layer is disclosed. A photoresist layer is formed over a substrate. The photoresist layer has a first photo region and a second photo region. A first exposure is performed to define a through pitch pattern at the first photo region and a second exposure is performed to define a dense pattern at the second photo region. The first exposure is performed by weak off-axis illumination (OAI) or disk illumination mode with a half tone phase shift mask (HTPSM). The second exposure is performed by strong OAI with HTPSM. In another embodiment, the second exposure is performed by disk illumination mode with a Levenson phase shift mask (PSM).

### BACKGROUND OF THE INVENTION

1. Field of the Invention

The present invention relates generally to photolithography, and more particularly, to a photolithographic method that can achieve good resolution and improve the common photo process window for both dense patterns and through pitch patterns.

2. Description of the Related Art

Photolithography is one of the critical steps in an integrated circuit (IC) fabrication process. As the density of the IC increases, the minimum pitch and the critical dimension (CD) of an IC device become smaller. Especially when the pitch of an IC device is smaller than 0.3 um and the critical dimension after photo development (DCD) of the IC device is smaller than 0.16 um, the through pitch photo process window and the critical dimension uniformity (CDU) of the hole patterns become a tough challenge.

One photolithographic approach for a dense pattern is the separate minimum pitch method, which divides the dense pattern mask into two masks each of which has a pitch that doubles the original pitch of the dense pattern mask. However, the cost and the complexity of this separate minimum pitch method are high due to the two-photo-two-etch process. In addition, the separate minimum pitch method has a very tight overlay budget.

Another photolithographic approach for a dense pattern is the one mask method, which applies the strong off-axis illumination (OAI) with a half tone phase shift mask (HTPSM). Although the one mask method can obtain more photo process window for a dense pattern, it will induce a severe proximity effect for a through pitch pattern, especially for an iso pattern. The severe proximity effect will lead to worse CDU and reduced photo process window.

In order to reduce the severe proximity effect, assist features (AF) could be added to a through pitch pattern or an iso pattern. However, the AF will make the optical proximity correction (OPC) rule more difficult to implement, and also increase the risk of AF print out. Another method to overcome the severe proximity effect is to apply the conventional illumination mode with a Levenson phase shift mask (PSM). However, the Levenson PSM can achieve good resolution and obtain more photo process window only for regular dense patterns. For through pitch patterns, the phase assist feature of the Levenson PSM is difficult to design. Furthermore, Levenson PSM will also result in reduced photo process window for through pitch patterns, especially for iso patterns.

In view of the foregoing, there is a need for a new photolithographic method that will achieve good resolution and improve the common photo process window for both dense patterns and through pitch patterns.

### SUMMARY OF THE INVENTION

Broadly speaking, the present invention fills this need by providing a photolithographic method that can achieve good resolution and improve the common photo process window for both dense patterns and through pitch patterns.

In accordance with one aspect of the present invention, a photolithographic method is provided. A photoresist layer is formed over a substrate. The formed photoresist layer has a first photo region and a second photo region. A first exposure is performed by a first illumination with a half tone phase shift mask (HTPSM) to define a through pitch pattern at the first photo region. A second exposure is performed by a second illumination with HTPSM to define a dense pattern at the second photo region. The first illumination is weak off-axis illumination (OAI) or disk illumination mode. The second illumination is strong OAI. If desired, the order of the first exposure and the second exposure could be reversed.

In accordance with another aspect of the present invention, another photolithographic method is provided. A photoresist layer is formed over a substrate. The formed photoresist layer has a first photo region and a second photo region. A first exposure is performed by a first illumination and a first mask to define a through pitch pattern at the first photo region. A second exposure is performed by a second illumination and a second mask to define a dense pattern at the second photo region. The first illumination is weak OAI or disk illumination mode and the first mask is HTPSM. The second illumination is disk illumination mode and the second mask is a Levenson phase shift mask (PSM). If desired, the order of the first exposure and the second exposure could be reversed.

In accordance with a further aspect of the present invention, yet another photolithographic method is provided. A photoresist layer is formed over a substrate. The photoresist layer has a first photo region and a second photo region. A first exposure is performed at the first photo region and a second exposure is performed at the second photo region.

In one embodiment, the first exposure defines a through pitch pattern at the first photo region and the second exposure defines a dense pattern at the second photo region. The first exposure is performed by weak OAI or disk illumination mode with HTPSM. The second exposure is performed by strong OAI with HTPSM. In another embodiment, the second exposure is performed by disk illumination mode with Levenson PSM.

In another embodiment, the first exposure defines a dense pattern at the first photo region and the second exposure defines a through pitch pattern at the second photo region. The first exposure is performed by strong OAI with HTPSM. In another embodiment, the first exposure is performed by disk illumination mode with Levenson PSM. The second exposure is performed by weak OAI or disk illumination mode with HTPSM.

It is to be understood that the foregoing general description and the following detailed description are exemplary and explanatory only and are not restrictive of the invention, as claimed.

### BRIEF DESCRIPTION OF THE DRAWINGS

The accompanying drawings, which are incorporated in and constitute part of this specification, illustrate exemplary embodiments of the invention and together with the description serve to explain the principles of the invention.

FIG. 1 is a flowchart showing the steps of a photolithographic method in accordance with one embodiment of the present invention.

FIG. 2 is a flowchart showing the steps of a photolithographic method in accordance with one embodiment of the present invention.

FIG. 3(a)-(d) show cross-sectional views of a wafer to demonstrate an exemplary photolithographic method in accordance with one embodiment of the present invention.

### DETAILED DESCRIPTION OF THE EXEMPLARY EMBODIMENTS

Reference is made in detail to embodiments of the invention. While the invention is described in conjunction with the embodiments, the invention is not intended to be limited by these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, as is obvious to one ordinarily skilled in the art, the invention may be practiced without these specific details. In other instances, well-known methods, procedures, components, and circuits have not been described in detail so that aspects of the invention will not be obscured.

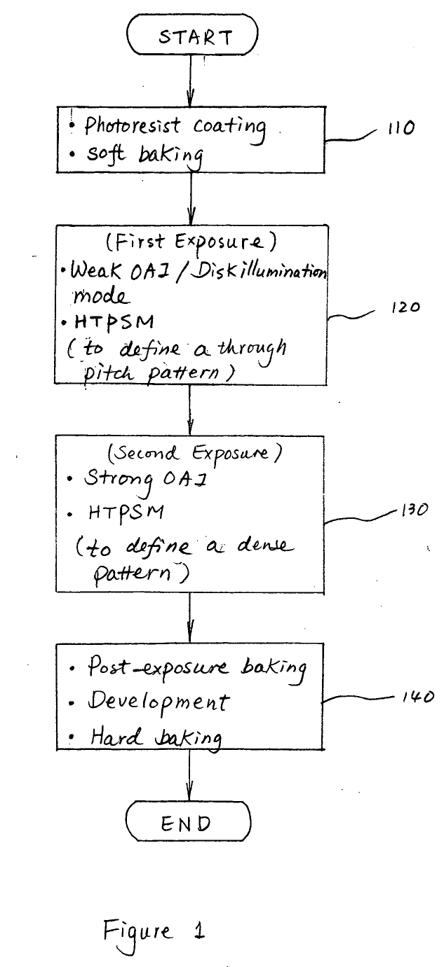

Referring initially to FIG. 1, a flowchart 100 is shown illustrating the steps of a photolithographic method for a substrate in accordance with one embodiment of the present invention. A dense pattern and a through pitch pattern are to be formed on the surface of the substrate.

In step 10, a photoresist layer is formed over the substrate. The photoresist layer is then soft baked to drive off most of the solvent in the photoresist layer.

In step 120, a first exposure is performed to define a through pitch pattern on the photoresist layer. The illumination for the first exposure is weak off-axis illumination (OAI) or disk illumination mode, and the mask is a half tone phase shift mask (HTPSM). In one embodiment, the weak OAI annular is conducted utilizing a set feature size of numerical aperture (NA)=0.6 to 0.75, sigma in=0.3 to 0.45, and sigma out=0.6 to 0.85 for HTPSM. In another embodiment, the weak OAI quasar is conducted utilizing a set feature size of NA=0.6 to 0.75, sigma in=0.3 to 0.45, sigma out=0.6 to 0.85, and angle=35 to 90 degree for HTPSM. In yet another embodiment, the weak OAI dipole is conducted utilizing a set feature size of NA=0.6 to 0.75, sigma in=0.3 to 0.45, sigma out=0.6 to 0.85, and X or Y angle=35 to 90 degree for HTPSM. . In still another embodiment, the disk illumination mode utilizes a set feature size of NA=0.5 to 0.65 and sigma out=0.4 to 0.7 for HTPSM.

In step 130, a second exposure is performed to define a dense pattern on the photoresist layer. The illumination for the second exposure is strong OAI and the mask is HTPSM. In one embodiment, the strong OAI annular is conducted utilizing a set feature size of NA=0.65 to 0.85, sigma in=0.55 to 0.75, and sigma out=0.75 to 0.95 for HTPSM. In another embodiment, the strong OAI quasar is conducted utilizing a set feature size of NA=0.65 to 0.85, sigma in=0.55 to 0.75, sigma out=0.75 to 0.95, and angle=15 to 45 degree for HTPSM. In yet another embodiment, the strong OAI dipole is conducted utilizing a set feature size of NA=0.65 to 0.85, sigma in=0.55 to 0.75, sigma out=0.75 to 0.95, and X or Y angle=15 to 45 degree for HTPSM. In an alternative embodiment, the order in which step 120 (the first exposure) and step 130 (the second exposure) are performed can be reversed.

In step 140, a post-exposure bake follows immediately after the second exposure. Then, the photoresist layer is developed to form the exposed photo patterns. Thereafter, a hard bake, i.e., a post-development thermal bake, is performed to evaporate the remaining solvent in the photoresist layer and improve the adhesion of the photoresist layer to the substrate surface.

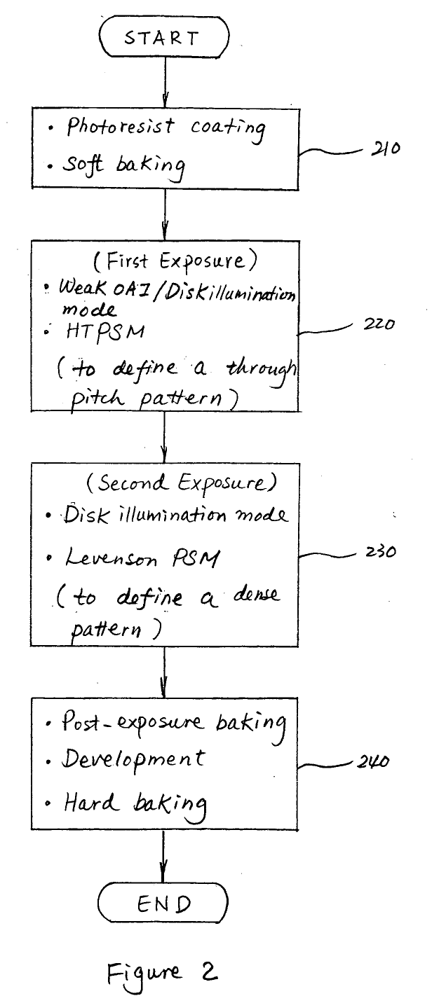

Referring now to FIG. 2, a flowchart 200 is shown to illustrate the steps of a photolithographic method for a substrate in accordance with one embodiment of the present invention. A dense pattern and a through pitch pattern are to be formed on the surface of the substrate.

In step 210, a photoresist layer is formed over the substrate. The photoresist layer is then soft baked to drive off most of the solvent in the photoresist layer.

In step 220, a first exposure is performed to define a through pitch pattern on the photoresist layer. The illumination for the first exposure is weak OAI or disk illumination mode. The mask for the first exposure is HTPSM. In one embodiment, the weak OAI annular is conducted utilizing a set feature size of numerical aperture (NA)=0.6 to 0.75, sigma in=0.3 to 0.45, and sigma out=0.6 to 0.85 for HTPSM. In another embodiment, the weak OAI quasar is conducted utilizing a set feature size of NA=0.6 to 0.75, sigma in=0.3 to 0.45, sigma out=0.6 to 0.85, and angle=35 to 90 degree for HTPSM. In yet another embodiment, the weak OAI dipole is conducted utilizing a set feature size of NA=0.6 to 0.75, sigma in=0.3 to 0.45, sigma out=0.6 to 0.85, and X or Y angle=35 to 90 degree for HTPSM. In still another embodiment, the disk illumination mode utilizes a set feature size of NA=0.5 to 0.65 and sigma out=0.4 to 0.7 for HTPSM.

In step 230, a second exposure is performed to define a dense pattern on the photoresist layer. The illumination for the second exposure is disk illumination mode and the mask is a Levenson phase shift mask (PSM). In one embodiment, the disk illumination mode utilizes a set feature size of NA=0.65 to 0.85 and sigma out=0.2 to 0.45 for Levenson PSM. In an alternative embodiment, the order in which step 220 (the first exposure) and step 230 (the second exposure) are performed can be reversed.

In step 240, a post-exposure bake follows immediately after the second exposure. Then, the photoresist layer is developed to form the exposed photo patterns. Thereafter, a hard bake, i.e., a post-development thermal bake, is performed to evaporate the remaining solvent in the photoresist layer and to improve the adhesion of the photoresist layer to the substrate surface.

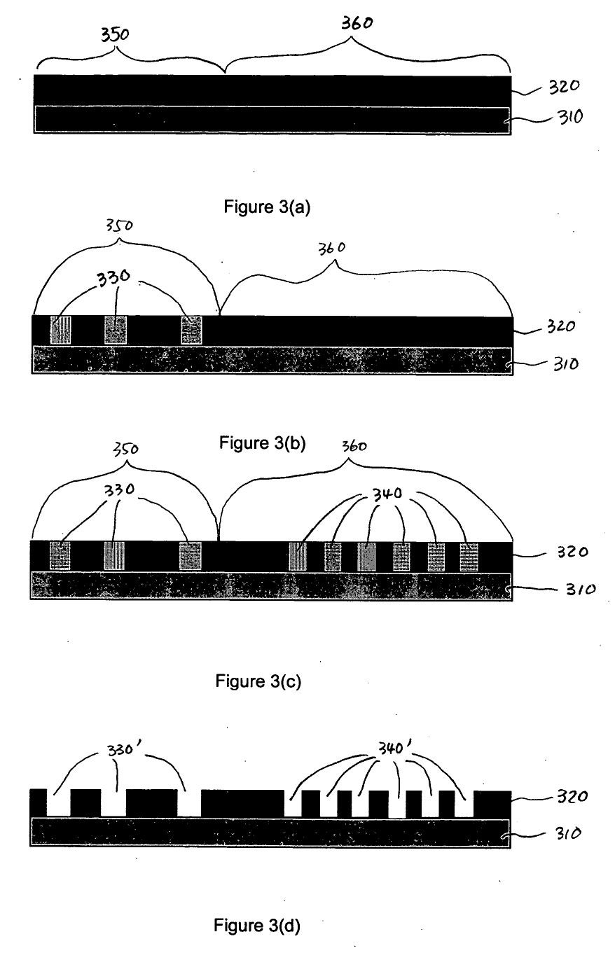

Referring now to FIG. 3(a)-(d), cross-sectional views of a wafer 300 are shown to demonstrate an exemplary photolithographic method in accordance with one embodiment of the present invention.

As shown in FIG. 3(a), a photoresist layer 320 is formed over the surface of the substrate 310. According to the patterns to be printed, the photoresist layer 320 is divided into two photo regions: a through pitch pattern photo region 350 and a dense pattern photo region 360. For example, the through pitch pattern photo region 350 could be used to print out the patterns of a peripheral circuit of the wafer 300, and the dense pattern photo region 360 could be used to print out the patterns of a memory array. In one embodiment, the photoresist layer 320 is a positive photoresist layer.

As shown in FIG. 3(b), the photoresist layer 320 has undergone a first exposure to define a through pitch pattern at the through pitch pattern photo region 350 of the photoresist 320. For the first exposure, the illumination is weak OAI and the mask is HTPSM. In an alternative embodiment, the illumination is disk illumination mode and the mask is HTPSM. The first exposure results in the soluble random through pitch areas 330 at the through pitch pattern photo region 350 of the photoresist layer 320. After the first exposure, the wafer 300 will not be unloaded and no development is performed.

As shown in FIG. 3(c), the photoresist layer 320 has undergone a second exposure to define a dense pattern at the dense pattern photo region 360 of the photoresist layer 320. For the second exposure, the illumination is strong OAI and the mask is HTPSM. In an alternative embodiment, the illumination is disk illumination mode and mask is a Levenson phase shift mask (PSM). The second exposure results in the soluble regular dense areas 340 at the dense pattern photo region 360 of the photoresist layer 320.

As shown in FIG. 3(d), a post-exposure bake is performed for the exposed photoresist layer 320 immediately after the second exposure. Then, a development is performed for the photoresist layer 320 to dissolve the soluble random through pitch areas 330 and the soluble regular dense areas 340. Thereafter, a hard bake, i.e., a post-development thermal bake, is performed to evaporate the remaining solvent in the photoresist layer 320 and to improve the adhesion of the photoresist layer 320 to the surface of the substrate 310. As a result, the random through pitch windows 330′ and the regular dense windows 340′ are formed on the photoresist layer 320.

The present invention forms a through pitch pattern and a dense pattern separately by using different illuminations and masks. The through pitch photo process window and the critical dimension uniformity (CDU) can be improved during the first exposure for the through pitch pattern and the good resolution can be achieved during the second exposure for the dense pattern. Because the through pitch photo process window is improved by the first exposure, the common photo process window, which is conventionally limited by the through pitch photo process window, will be improved for the dense pattern and the through pitch pattern. The present invention has no complex optical proximity correction (OPC) or phase assignment, as compared with the one mask method. And, the present invention has less production cost and more overlay budget than the separate minimum pitch method. Furthermore, the present invention also processes the features of reduced die size and friendly layout.

The foregoing descriptions of specific embodiments of the invention have been presented for purposes of illustration and description. They are not intended to be exhaustive or to limit the invention to the precise forms disclosed. Obviously, many modifications and variations are possible in light of the above teaching. The embodiments were chosen and described in order to explain the principles and the application of the invention, thereby enabling others skilled in the art to utilize the invention in its various embodiments and modifications according to the particular purpose contemplated. The scope of the invention is intended to be defined by the claims appended hereto and their equivalents.

What is claimed is:

1. A method for forming photo patterns, comprising:
providing a substrate;
forming a photoresist layer over the substrate, the photoresist layer having a first photo region and a second photo region;
performing a first exposure with a first illumination and a mask to define a through pitch pattern at the first photo region; and
performing a second exposure with a second illumination and the mask to define a dense pattern at the second photo region.

2. The method for forming photo patterns as recited in claim 1, further comprising:
soft baking the photoresist layer after the forming of the photoresist layer.

3. The method for forming photo patterns as recited in claim 1, further comprising:
post-exposure baking the photoresist layer after the second exposure;
developing the photoresist layer; and
hard baking the photoresist layer.

4. The method for forming photo patterns as recited in claim 1, wherein the photoresist layer is a positive photoresist layer.

5. The method for forming photo patterns as recited in claim 1, wherein the first illumination is weak off-axis illumination (OAI) or disk illumination mode.

6. The method for forming photo patterns as recited in claim 5, wherein the weak OAI is conducted utilizing a set feature size of numerical aperture (NA) ranging from about 0.6 to about 0.75, sigma in ranging from about 0.3 to about 0.45, and sigma out ranging from about 0.6 to about 0.85.

7. The method for forming photo patterns as recited in claim 5, wherein the disk illumination mode is defined by a set feature size of NA ranging from about 0.5 to about 0.65 and sigma out ranging from about 0.4 to about 0.7.

8. The method for forming photo patterns as recited in claim 1, wherein the second illumination is strong OAI.

9. The method for forming photo patterns as recited in claim 8, wherein the strong OAI is conducted utilizing a set feature size of NA ranging from about 0.65 to about 0.85, sigma in ranging from about 0.55 to about 0.75, and sigma out ranging from about 0.75 to about 0.95.

10. The method for forming photo patterns as recited in claim 1, wherein the mask is a half tone phase shift mask (HTPSM).

11. A method for forming photo patterns, comprising:
providing a substrate;
forming a photoresist layer over the substrate, the photoresist layer having a first photo region and a second photo region;
performing a first exposure with a first illumination and a first mask to define a through pitch pattern at the first photo region; and
performing a second exposure with a second illumination and a second mask to define a dense pattern at the second photo region.

12. The method for forming photo patterns as recited in claim 11, further comprising:
soft baking the photoresist layer after the forming of the photoresist layer.

13. The method for forming photo patterns as recited in claim 11, further comprising:
post-exposure baking the photoresist layer after the second exposure;
developing the photoresist layer; and
hard baking the photoresist layer.

14. The method for forming photo patterns as recited in claim 11, wherein the photoresist layer is a positive photoresist layer.

15. The method for forming photo patterns as recited in claim 11, wherein the first illumination is weak OAI or disk illumination mode.

16. The method for forming photo patterns as recited in claim 15, wherein the weak OAI is conducted utilizing a set feature size of numerical aperture (NA) ranging from about 0.6 to about 0.75, sigma in ranging from about 0.3 to about 0.45, and sigma out ranging from about 0.6 to about 0.85.

17. The method for forming photo patterns as recited in claim 15, wherein the disk illumination mode is defined by a set feature size of NA ranging from about 0.5 to about 0.65 and sigma out ranging from about 0.4 to about 0.7.

18. The method for forming photo patterns as recited in claim 11, wherein the first mask is HTPSM.

19. The method for forming photo patterns as recited in claim 11, wherein the second illumination is disk illumination mode and the second mask is a Levenson phase shift mask (PSM).

20. A method for forming photo patterns, comprising:
providing a substrate;
forming a photoresist layer over the substrate, the photoresist layer having a first photo region and a second photo region;
performing a first exposure at the first photo region; and
performing a second exposure at the second photo region.

21. The method for forming photo patterns as recited in claim 20, wherein the first exposure defines a through pitch pattern and the second exposure defines a dense pattern.

22. The method for forming photo patterns as recited in claim 21, wherein the first exposure is performed by weak OAI or disk illumination mode with HTPSM.

23. The method for forming photo patterns as recited in claim 22, wherein the weak OAI is conducted utilizing a set feature size of numerical aperture (NA) ranging from about 0.6 to about 0.75, sigma in ranging from about 0.3 to about 0.45, and sigma out ranging from about 0.6 to about 0.85.

24. The method for forming photo patterns as recited in claim 22, wherein the disk illumination mode is defined by a set feature size of NA ranging from about 0.5 to about 0.65 and sigma out ranging from about 0.4 to about 0.7.

25. The method for forming photo patterns as recited in claim 21, wherein the second exposure is performed by strong OAI with HTPSM.

26. The method for forming photo patterns as recited in claim 25, wherein the strong OAI is conducted utilizing a set feature size of NA ranging from about 0.65 to about 0.85, sigma in ranging from about 0.55 to about 0.75, and sigma out ranging from about 0.75 to about 0.95.

27. The method for forming photo patterns as recited in claim 21, wherein the second exposure is performed by disk illumination mode with Levenson PSM.

28. The method for forming photo patterns as recited in claim 20, wherein the first exposure defines a dense pattern and the second exposure defines a through pitch pattern.

29. The method for forming photo patterns as recited in claim 28, wherein the first exposure is performed by strong OAI with HTPSM.

30. The method for forming photo patterns as recited in claim 29, wherein the strong OAI is conducted utilizing a set feature size of NA ranging from about 0.65 to about 0.85, sigma in ranging from about 0.55 to about 0.75, and sigma out ranging from about 0.75 to about 0.95.

31. The method for forming photo patterns as recited in claim 28, wherein the first exposure is performed by disk illumination mode with Levenson PSM.

32. The method for forming photo patterns as recited in claim 28, wherein the second exposure is performed by weak OAI or disk illumination mode with HTPSM.

33. The method for forming photo patterns as recited in claim 32, wherein the weak OAI is conducted utilizing a set feature size of numerical aperture (NA) ranging from about 0.6 to about 0.75, sigma in ranging from about 0.3 to about 0.45, and sigma out ranging from about 0.6 to about 0.85.

34. The method for forming photo patterns as recited in claim 32, wherein the disk illumination mode is defined by a set feature size of NA ranging from about 0.5 to about 0.65 and sigma out ranging from about 0.4 to about 0.7.
